(19) United States
(12) Patent Application Publication
(10) Pub. No.: US 2014/0184244 A1
(43) Pub. Date: Jul. 3, 2014

(54) INDUCTIVE SENSOR

(71) Applicant: SICK AG, Waldkirch/Breisgau (DE)

(72) Inventor: Olaf MACHUL, Merzhausen (DE)

(73) Assignee: SICK AG, Waldkirch/Breisgau (DE)

(21) Appl. No.: 14/140,144

(22) Filed: Dec. 24, 2013

(30) Foreign Application Priority Data
Dec. 27, 2012 (DE) 102012224386.0

(51) Int. Cl. G01R 1/04

(52) U.S. Cl. CPC G01R 1/04
USPC 324/654

(57) ABSTRACT

An inductive sensor comprises a window-less full metal housing which is designed as a single-piece injection molded component and is completely produced from amorphous metal.

The present invention relates to an inductive sensor having a full metal housing.

Such sensors are also known as “inductive full metal sensors” and are used, for example, as proximity switches. The sensor can be fastened to a respective carrier component at the desired insulation site by means of the housing, for example with the aid of a thread formed at the housing.

As a rule, inductive full metal sensors have a housing of stainless steel or of nickelplated brass. In the manufacture of conventional full metal housings, complex worksteps and/or worksteps having tolerances are frequently required such as deep drawing, turning or metal injection molding (MIM). A further problem is the comparatively high electrical conductivity of brass and stainless steel. In a housing wall having good electrical conductivity, eddy currents are namely generated by the excitation resonant circuit present in the interior of the housing, which acts against the measurement principle of generating eddy currents in an outer moved target. This unwanted effect can be alleviated by a reduction in the wall thickness of the housing. However, this is associated with an unwanted reduction in the stability of the sensor.

To reduce the above-named problems, it would generally be possible to move away from the concept of the full metal sensor in that the sensor housing is provided with a window into which a wall piece of a dielectric material is inserted. Such a window allows a largely loss-free passage of the excitation vibrations through the housing wall. However, inductive sensors having such dielectric housing windows are not suitable for many applications since they e.g. do not have the required resistance with respect to mechanical load, temperature fluctuations or corrosive environments. In addition, the insertion of a window into a housing body requires additional work steps which make the manufacturing process more expensive. A window-less full metal sensor is more robust and more versatile in comparison with sensors having dielectric windows.

The full metal housing can also be designed as window-less and have regions of amorphous metal. Amorphous metal materials which are also known as “metallic glasses” have a relatively small electric conductivity in comparison with steel due to their non-crystalline structure so that the housing-induced eddy current losses are reduced on the passage of the excitation vibrations through an amorphous region.

For example, such a sensor having amorphous housing regions comprises a transmitter arranged in the housing for generating an electric eddy field, with those regions of the housing which are exposed to the electric eddy field during the operation of the transmitter being produced from amorphous metal. It is ensured in this manner that the eddy current losses are minimized on the passing of the excitation fields through the housing.

A front plate or a front cap of the housing can in particular be made from amorphous metal. The front region of the housing as a rule corresponds to that section which is primarily exposed to the electromagnetic excitation waves. The housing-induced eddy current losses can be restricted, to a minimum by forming this region from amorphous metal.

DE 10 2012 203 449 A1 discloses an inductive proximity switch in which the excitation coil and the coil core are embedded in a sealant of glass and in which the front plate of the housing comprises amorphous metal.

In DE 100 18 269 B4 a magnetic position measuring device is disclosed which has a magnetic measuring graduation to be attached to a component and which has a sensor head to be moved along the measuring graduation. The sensor head has a magnetic field detector which is arranged in a recess of the carrier element. The detector is covered by a thin, non-magnetic metallic foil which can be composed of an amorphous iron-nickel alloy.

EP 2 015 030 A2 discloses a pen tablet having a reception coil across which a two-layer cover plate extends. One layer of the cover plate is produced from an amorphous metal.

It is an object of the invention to simplify the manufacture of inductive full metal sensors and to increase their sensitivity.

The object is satisfied by an inductive sensor having the features of claim 1.

In accordance with the invention, the full metal housing is produced completely of amorphous metal. This allows a particularly simple construction.

In addition, the strength and the hardness of amorphous metals are increased in comparison with crystalline metals. This increased strength makes it possible to design the housing with thinner walls with a predefined stability. The more thin-walled the housing is, the lower the unwanted eddy current losses are. The sensitivity of an inductive full metal sensor can thus be considerably increased by the use of amorphous metals as the material of the housing.

A further advantage of the use of amorphous metals in the manufacture of sensor housings is that amorphous metals have comparatively small shrinkage rates and can therefore be manufactured in a tool-specific manner by means of processes similar to injection molding.

The invention accordingly provides configuring the housing of amorphous metal as an injection molded component. This allows a particularly simple, fast and inexpensive manufacture. On a use of crystalline metals, a manufacture by means of injection molding would generally be precluded due to the high shrinkage rates.

In accordance with the invention, the housing is moreover configured in one piece. A particularly simple, robust and stable design is thereby ensured.

Further developments of the invention set forth in the dependent claims, in the description and in the enclosed drawings.

The amorphous metal can in particular be an amorphous metal alloy. Such amorphous metal alloys are available in different embodiments and are relatively inexpensive in comparison with alternative crystalline metals having smaller conductivity such as titanium. The type of the alloy can be tailored to the respective use.

The amorphous metal is preferably not magnetically conductive.

In accordance with an embodiment of the invention, at least the regions of the housing produced from the amorphous metal have a wall thickness of at most 0.5 mm, preferably at most 0.3 mm, and particularly preferably at most 0.2 mm. Such small wall thicknesses cannot be realized in the required stability using crystalline metals. The sensitivity of the inductive sensor can, however, be considerably increased by such thin housing walls.

The invention will be described in the following by way of example with reference to the drawing.

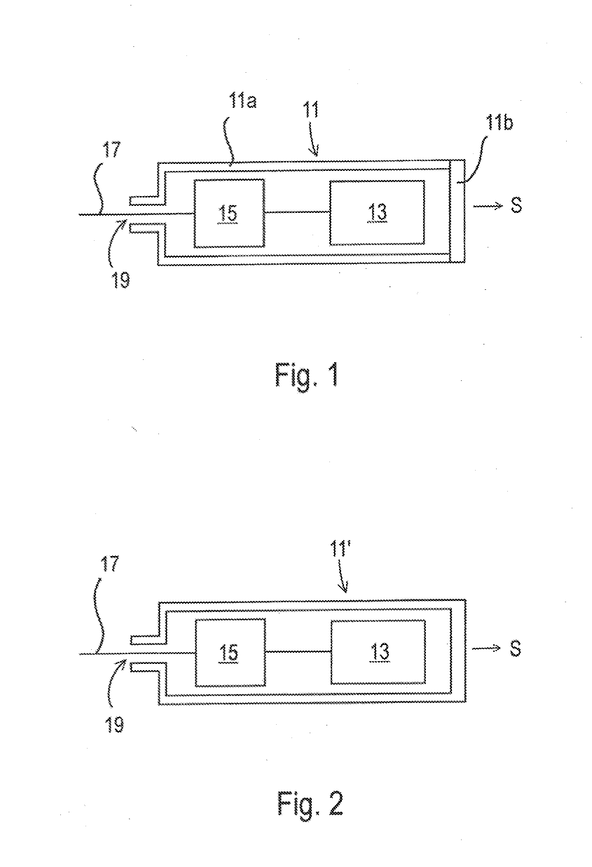

FIG. 1 shows a simplified side sectional view of an inductive sensor not forming part of the invention; and

FIG. 2 shows a simplified side sectional view of an inductive sensor in accordance with an embodiment of the invention;

FIG. 1 shows an inductive proximity sensor which does not form part of the invention and which has a full metal housing 11. The full metal housing 11 comprises a substantially hollow cylindrical base section 11a which is closed by a front plate 11b at a front end. A transmitter 13 known per se for producing electromagnetic excitation vibrations as well as an electronic evaluation unit 15 in communication with the transmitter 13 are accommodated in the interior of the full metal housing 11. The electronic evaluation unit 15 outputs a sensor signal via a signal line 17, said sensor signal indicating the position of a target, not shown. The signal line 17 is led outwardly through a lead through 19 which is provided at a rear end of the full metal housing 11.

In the sensor shown in FIG. 1, the hollow cylindrical base section 11a is produced from stainless steel, while the front plate 11b is produced from an amorphous metal alloy. In particular amorphous metal alloys based on zirconium and titanium can be used. The main irradiation direction S of the transmitter 13 faces in the direction of the front plate 11b so that the excitation fields only pass through a housing wall of amorphous metal. Eddy current losses in the full metal housing 11 are thereby largely avoided. In addition, due to the great hardness and strength of the amorphous metal material, the front plate 11b can be designed as relatively thin, for example in a wail thickness of 0.2 mm, whereby the eddy current losses are further reduced. The inductive sensor thus has a considerably higher sensitivity than would be possible using a housing completely produced from stainless steel or brass.

An inductive sensor in accordance with the invention is shown in FIG. 2, with the full metal housing 11′ here being completely produced from an amorphous metal alloy. There is a particular advantage in this respect in that the manufacture can take place in tool-specific manner by means of a process similar to injection molding and thus particularly simply and inexpensively. The manufacture in a process similar to injection molding moreover allows greater design freedom.

Other types of inductive sensors such as inductive magnetic field sensors, filling level sensors or the like can generally also be provided with a full metal housing of amorphous metal.

### REFERENCE NUMERAL LIST

11, 11′ full metal housing
11a base section
11b front plate
13 transmitter
15 electronic evaluation unit
17 signal line
19 leadthrough
S main irradiation direction

1. An inductive sensor having a window-less full metal housing, wherein the full metal housing (11′) is designed as a single-piece injection molded component and is completely produced from amorphous metal.

2. The sensor in accordance with claim 1, wherein the amorphous metal is an amorphous metal alloy.

3. The sensor in accordance with claim 1, wherein the amorphous metal is not magnetically conductive.

4. The sensor in accordance with claim 1, wherein at least the regions of the. full metal housing (11′) produced from the amorphous metal have a wall thickness of at most 0.5 mm.

5. The sensor in accordance with claim 4, wherein at least the regions of the full metal housing (11′) produced from the amorphous metal have a wall thickness of at most 0.3 mm.

6. The sensor in accordance with claim 4, wherein at least the regions of the full metal housing (11′) produced from the amorphous metal have a wall thickness of at most 0.2 mm.
